(19) United States
(12) Patent Application Publication
(10) Pub. No.: US 2017/0003363 A1
(43) Pub. Date: Jan. 5, 2017

(54) SYSTEM AND METHOD FOR FREE RADICAL IMAGING

(71) Applicants: Matthew S. Rosen, Somerville, MA (US); Mathieu Sarracanie, Somerville, MA (US); Brandon Armstrong, Brighton, MA (US)

(72) Inventors: Matthew S. Rosen, Somerville, MA (US); Mathieu Sarracanie, Somerville, MA (US); Brandon Armstrong, Brighton, MA (US)

(21) Appl. No.: 15/125,846

(22) PCT Filed: Mar. 13, 2015
(86) PCT No.: PCT/US15/20516

§ 371 Date: Sep. 13, 2016

Related U.S. Application Data
(60) Provisional application No. 61/953,441, filed on Mar. 14, 2014.

(51) Int. Cl. G01R 33/44; G01R 33/56; G01R 33/60

(52) U.S. Cl. CPC G01R 33/445; G01R 33/60; G01R 33/56

(57) ABSTRACT

A system and method for performing a medical imaging process includes arranging a subject to be imaged in a magnetic resonance imaging (MRI) system and performing, using the MRI system, a magnetic resonance (MR) imaging pulse sequence. While performing the MR pulse sequence, electron paramagnetic resonance (EPR) pulses are performed at least during the application of the phase encoding gradients or only during the MR pulse sequence. Data is acquired that corresponds to signals from the subject excited by the MR pulse sequence and the EPR pulses. At least one image of the subject is reconstructed from the data.

### CROSS-REFERENCE TO RELATED APPLICATIONS

This application is based on, claims priority to, and incorporates herein by reference, U.S. Provisional Application Ser. No. 61/953,441, filed Mar. 14, 2014, and entitled “SYSTEM AND METHOD FOR ASSESSING FREE RADICALS USING MAGNETIC RESONANCE IMGAGING SYSTEMS.”

### STATEMENT REGARDING FEDERALLY SPONSORED RESEARCH

This invention was made with government support under W81XWH-11-2-076 awarded by the Department of Defense. The government has certain rights in the invention.

### BACKGROUND

The present disclosure relates to systems and methods for the invention is magnetic resonance imaging (MRI). More particularly, the present disclosure relates to systems and methods for accelerating EPR and MRI processes.

When a substance such as human tissue is subjected to a uniform magnetic field (polarizing field B₀), the individual magnetic moments of the excited nuclei in the tissue attempt to align with this polarizing field, but precess about it in random order at their characteristic Larmor frequency. If the substance, or tissue, is subjected to a magnetic field (excitation field B₁) which is in the x-y plane and which is near the Larmor frequency, the net aligned moment, M_{z}, may be rotated, or “tipped”, into the x-y plane to produce a net transverse magnetic moment Mₜ. A signal is emitted by the excited nuclei or “spins”, after the excitation signal B₁ is terminated, and this signal may be received and processed to form an image.

When utilizing these “MR” signals to produce images, magnetic field gradients (Gₓ, G_{y}, and G_{z}) are employed. Typically, the region to be imaged is scanned by a sequence of measurement cycles in which these gradients vary according to the particular localization method being used. The resulting set of received MR signals are digitized and processed to reconstruct the image using one of many well known reconstruction techniques.

Traditional MRI is performed by exciting and detecting emitted nuclear MR (NMR) signals using transmit and receive coils, respectively (often referred to as radio frequency (RF) coils). Transmit/receive coils may include separate coils for transmitting and receiving, multiple coils for transmitting and/or receiving, or the same coils for transmitting and receiving. Transmit/receive coils are also often referred to as Tx/Rx or Tx/Rx coils to generically refer to the various configurations for the transmit and receive magnetic component of an MRI system. These terms are used interchangeably herein.

In traditional nuclear MRI, transmit coils generate a pulsed magnetic field B1 having a frequency related to the rate of precession of proton spins of the atoms in the magnetic field B0 to cause the net magnetization of the protons to develop a component in a direction transverse to the direction of the B0 field. After the B1 field is turned off, the transverse component of the net magnetization vector precesses, its magnitude decaying over time until the net magnetization re-aligns with the direction of the B0 field. This process produces MR signals that can be detected by voltages induced in one or more receive coils of the MRI system. Nuclear MRI relies upon nuclear polarization.

Imaging of free radicals is useful in a number of important physiological processes such as mapping of pO2, mapping free radical distribution and metabolism, performing molecular imaging, and monitoring changes in local viscosity. However, there is currently no non-invasive process for imaging free radicals. Though techniques have been developed to exploit the Overhauser effect to image free radicals, these techniques cannot be used on live tissue. These techniques involve applying an electron paramagnetic resonance (EPR) pulse sequence at the saturation or resonance frequency of electrons to polarize the electron spins. The Overhauser effect is the physical phenomenon whereby this electron spin polarization is transferred to protons in the nucleus. The transferred polarization can then be detected using nuclear MRI techniques. Due to the large magnetic moments of electron spins, the electron polarization is much larger than the proton counterparts (e.g., on the order of 600 times that of nuclear polarization). Thus, the presence of free radicals can be detected as enhanced NMR signals. This process is referred to as Overhauser enhanced MRI (OMRI) or proton electron double resonance imaging (PEDRI).

Conventional OMRI techniques are, however, not available for live subjects due to the extremely high electron saturation frequencies, which are on the order of 600 times higher than corresponding Larmor frequencies for proton resonance. For example, using a 3 tesla (T) MRI scanner, which has a resonant frequency of approximately 100 MHz, the corresponding electron saturation frequency is approximately 6 GHz. As a result, EPR pulse sequences are in the microwave range at clinical high-field strengths and would result in tissue destruction if performed in vivo. Thus, conventional OMRI techniques are not clinically useful,

### SUMMARY

In accordance with one aspect of the disclosure, a magnetic resonance imaging (MRI) system is disclosed that includes a magnet system configured to generate a static magnetic field about at least a region of interest (ROI) of a subject arranged in the MRI system and at least one gradient coil configured to establish at least one magnetic gradient field with respect to the static magnetic field. The system also includes a radio frequency (RF) system configured to deliver excitation pulses to the subject and a computer system. The computer system is programmed to control the at least one gradient coil and the RF system to perform a magnetic resonance (MR) imaging pulse sequence including application of phase encoding gradients and, while performing the MR pulse sequence, perform electron paramagnetic resonance (EPR) pulses at least during the application of the phase encoding gradients. The computer system is further programmed to acquire data corresponding to signals from the subject excited by the MR pulse sequence and the EPR pulses and reconstruct, from the data, at least one image of the subject.

In accordance with another aspect of the disclosure, a method is provided for performing a medical imaging process. The method includes arranging a subject to be imaged in a magnetic resonance imaging (MRI) system and performing, using the MRI system, a magnetic resonance (MR) imaging pulse sequence having a repetition time (TR). The method also includes performing electron paramagnetic resonance (EPR) pulses while performing the MR pulse sequence, such that the EPR pulses are only performed within each TR of the MR pulse sequence. Furthermore, the method includes acquiring data corresponding to signals from the subject excited by the MR pulse sequence and the EPR pulses and reconstructing, from the data, an image of the subject.

In accordance with yet another aspect of the disclosure, a low-field magnetic resonance imaging system is provided for detecting free radicals in a subject. The system includes a plurality of magnetic components that include at least one magnet configured to produce a low-field B0 magnetic field, at least one gradient coil configured to produce magnetic fields to encode nuclear magnetic resonance signals emitted from the subject, and at least one radio-frequency coil configured to produce excitation pulses. The system also includes at least one controller configured to control at least some of the plurality of magnetic components to produce pulse sequences wherein electron paramagnetic resonance pulses are applied during intervals in which the at least one gradient coil is operated

In accordance with still another aspect of the disclosure, a low-field magnetic resonance imaging system is provided for detecting free radicals in a subject. The system includes a plurality of magnetic components including at least one magnet configured to produce a low-field B0 magnetic field, at least one gradient coil configured to produce magnetic fields to encode magnetic resonance signals emitted from the subject, and at least one radio-frequency coil configured to produce excitation pulses. The system also includes at least one controller to control at least some of the plurality of magnetic components to produce steady-state free precession pulse sequences having in-sequence electron paramagnetic resonance pulses, and wherein the electron paramagnetic resonance pulses have a duration less than a corresponding nuclear T1.

The foregoing and other advantages of the invention will appear from the following description.

### BRIEF DESCRIPTION OF THE DRAWINGS

FIG. 1 is a block diagram of an MRI system.

FIG. 2 is a block diagram of an RF system of an MRI system.

FIG. 3 is a picture of a low-field MRI (IfMRI) system in accordance with the present disclosure.

FIG. 4A is a picture of an EPR coil for use the system of FIG. 3 and in accordance with the present disclosure.

FIG. 4B is a picture of a solenoid coil used for NMR excitation and detection with the coil of FIG. 4A and with the system of FIG. 3 in accordance with the present disclosure.

FIG. 5 is a pulse sequence diagram for a pulse sequence in accordance with the present disclosure.

FIG. 6A is a graphic illustrating an example of an undersampling (US) pattern used for 50 percent undersampling.

FIG. 6B is a graphic illustrating an example of an undersampling (US) pattern used for 70 percent undersampling.

FIG. 6C is a graphic illustrating an example of an undersampling (US) pattern used for 80 percent undersampling.

FIG. 6D is a graphic illustrating an example of an undersampling (US) pattern used for 90 percent undersampling.

FIG. 7 is a graph of simulated and measured data showing echo amplitudes acquired during the pulse sequence in FIG. 5 with only the read gradient active.

FIG. 8 is a graph showing MAE computed each slice number for each undersampling fraction with the phantom.

### DETAILED DESCRIPTION

Low-field MRI (e.g., 0.2 T, 0.1 T, 10 mT, 6.5 mT or less) provides a relatively low cost, high availability alternative to high-field MRI. The inventors have recognized that, in the low-field context, performing OMRI in vivo is feasible and have developed techniques to both accelerate OMRI acquisition and significantly reduce the specific absorption rate (SAR) of EPR pulse sequences. According to some configurations, a separate EPR saturation step, as used in conventional OMRI, is not required. Instead, the EPR and MRI pulse sequences can be combined or interleaved by coordinating the EPR pulses

The inventors have further appreciated that the duration that EPR pulses are turned on within each acquisition cycle can be significantly reduced by choosing an appropriate MRI pulse sequence. According to some configurations, a balanced steady state free precession (b-SSFP) sequence may be used to facilitate a reduction in the duration of the EPR pulses. In particular, because the b-SSFP sequence achieves steady-state magnetization, EPR pulses are not required to fully reestablish the magnetization on each acquisition cycle and therefore can be significantly reduced in duration (e.g., from 1 second in conventional OMRI to approximately 10 msec), thereby realizing substantial reductions in SAR and acquisition times.

As discussed above, OMRI utilizes the transfer of electron polarization to nuclear protons. For example, OMRI exploits the dipolar coupling between the unpaired electron of the free radical and the 1H nuclei of water to increase nuclear magnetization via dynamic nuclear polarization (DNP) and subsequently detects the enhanced nuclear spin polarization with MRI. OMRI provides a way to image free radical species as narrow NMR line widths enable imaging using reasonable-strength encoding gradients. OMRI also benefits from the ability to use traditional MRI sequences, though specialized hardware is needed to drive the electron spin resonance, and the sequences must be modified to allow for EPR saturation pulses.

A difficulty of OMRI is the need for high power radiofrequency (RF) to saturate the electron spins. Additionally, as EPR frequencies are two orders of magnitude higher than 1H frequencies, a high frequency resonator is required, and this leads to high specific absorption rate (SAR) and limited penetration depth. For these reasons, some of conceptualized OMRI as something that is to be performed at a low- to intermediate magnetic field or in a field-cycled setup. A typical field-cycled OMRI experiment begins at very-low magnetic field (˜5 mT) where EPR irradiation is applied for approximately the nuclear T1 of the sample at the irradiation magnetic field. The magnetic field is then quickly ramped up to the imaging field and a line or plane of k-space data is acquired. The magnetic field is then ramped down for EPR irradiation and repolarization because the DNP signal decays with the 1H nuclear T1.

Such a field-cycled OMRI technique can be used to address, in part, the problem that EPR pulses are in the microwave range at high-fields and therefore not useful for in vivo imaging. However, field-cycled OMRI comes at the cost of a slower and more complex scanning process than traditional MRI processes, due to the need to refresh the DNP-enhanced signal many times over the acquisition time. In particular, the need to cycle the B0 field not only significantly complicates the process, it adds to the total acquisition time. In addition, applying the EPR pulses for approximately the nuclear T1 (e.g., approximately 1 second) and having to do so on every cycle to reestablish the electron polarization is not only time consuming but leads to unacceptable levels of SAR.

The inventors have developed low-field MRI systems that do not need to cycle to high-field strengths to capture NMR data. As a result, there is no need for B0 field cycling and both EPR and NMR pulse sequences can remain in the low-field regime. Additionally, the inventors have recognized that instead of applying EPR pulses separate from the NMR pulse sequence, which adds significant time to each application of the pulse sequence, the EPR pulse sequence can be applied in-sequence, for example, during the gradient encode phase of the NMR pulse sequence. As a result, EPR pulses can be applied without increasing the duration of the NMR pulse sequence. Furthermore, the inventors have appreciated that by selecting an appropriate pulse sequence, the need to fully reestablish the electron polarization on each cycle is alleviated, allowing for significant reduction in the duration EPR pulses need be applied. For example, NMR pulse sequences that achieve steady state magnetization such as SSFP sequences can be used to reduce the duration of the EPR pulses, thus significantly reducing SAR. Undersampling can also be used to reduce the amount of data acquired, thus reducing the number of pulse sequence cycles that are applied and further reducing acquisition times and SAR. The above described techniques can be used alone or in any combination to facilitate free radical imaging in the low-field context.

According to some aspect of the disclosure, three-dimensional (3D) OMRI, using a low-field and constant B0 magnetic field, for example, a 6.5 mT field, is provided that achieves up to 7-fold acceleration compared to the fastest OMRI sequence reported. A balanced steady-state free precession (b-SSFP) pulse sequence may be used. The high acquisition efficiency of the b-SSFP pulse sequence is maintained by applying the Overhauser saturation pulses during a phase encode step and, thereby, controlling a time-consuming pre-irradiation step used by conventional OMRI techniques. Additionally, undersampling strategies and compressed sensing (CS) techniques can be used to increase the temporal resolution, while also reducing the total number of EPR RF pulses.

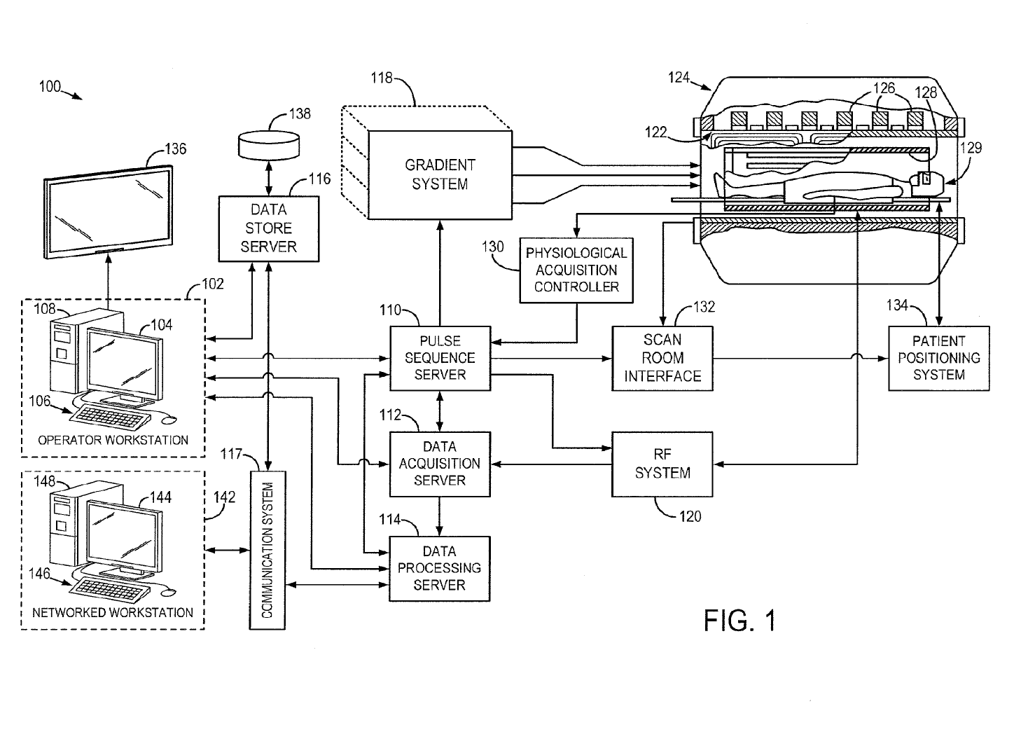

Referring particularly now to FIG. 1, an example of a magnetic resonance imaging (MRI) system 100 is illustrated. The MRI system 100 includes an operator workstation 102, which will typically include a display 104, one or more input devices 106, such as a keyboard and mouse, and a processor 108. The processor 108 may include a commercially available programmable machine running a commercially available operating system. The operator workstation 102 provides the operator interface that enables scan prescriptions to be entered into the MRI system 100. In general, the operator workstation 102 may be coupled to four servers: a pulse sequence server 110; a data acquisition server 112; a data processing server 114; and a data store server 116. The operator workstation 102 and each server 110, 112, 114, and 116 are connected to communicate with each other. For example, the servers 110, 112, 114, and 116 may be connected via a communication system 117, which may include any suitable network connection, whether wired, wireless, or a combination of both. As an example, the communication system 117 may include both proprietary or dedicated networks, as well as open networks, such as the internet.

The pulse sequence server 110 functions in response to instructions downloaded from the operator workstation 102 to operate a gradient system 118 and a radiofrequency (“RE”) system 120. Gradient waveforms necessary to perform the prescribed scan are produced and applied to the gradient system 118, which excites gradient coils in an assembly 122 to produce the magnetic field gradients Gₓ, G_{y}, and G_{z} used for position encoding magnetic resonance signals. The gradient coil assembly 122 forms part of a magnet assembly 124 that includes a polarizing magnet 126 and a whole-body RF coil 128 and/or local coil, such as a head coil 129.

RF waveforms are applied by the RF system 120 to the RF coil 128, or a separate local coil, such as the head coil 129, in order to perform the prescribed magnetic resonance pulse sequence. Responsive magnetic resonance signals detected by the RF coil 128, or a separate local coil, such as the head coil 129, are received by the RF system 120, where they are amplified, demodulated, filtered, and digitized under direction of commands produced by the pulse sequence server 110. The RF system 120 includes an RF transmitter for producing a wide variety of RF pulses used in MRI pulse sequences. The RF transmitter is responsive to the scan prescription and direction from the pulse sequence server 110 to produce RF pulses of the desired frequency, phase, and pulse amplitude waveform. The generated RF pulses may be applied to the whole-body RF coil 128 or to one or more local coils or coil arrays, such as the head coil 129.

The RF system 120 also includes one or more RF receiver channels. Each RF receiver channel includes an RF preamplifier that amplifies the magnetic resonance signal received by the coil 128/129 to which it is connected, and a detector that detects and digitizes the I and Q quadrature components of the received magnetic resonance signal. The magnitude of the received magnetic resonance signal may, therefore, be determined at any sampled point by the square root of the sum of the squares of the I and Q components:

M=\sqrt{I²+Q²} (1);

and the phase of the received magnetic resonance signal may also be determined according to the following relationship:

$$ϕ = {tan}^{- 1} ( \frac{Q}{I} ) . \qquad ( 2 )$$

The pulse sequence server 110 also optionally receives patient data from a physiological acquisition controller 130. By way of example, the physiological acquisition controller 130 may receive signals from a number of different sensors connected to the patient, such as electrocardiograph (“ECG”) signals from electrodes, or respiratory signals from a respiratory bellows or other respiratory monitoring device. Such signals are typically used by the pulse sequence server 110 to synchronize, or “gate,” the performance of the scan with the subject's heart beat or respiration.

The pulse sequence server 110 also connects to a scan room interface circuit 132 that receives signals from various sensors associated with the condition of the patient and the magnet system. It is also through the scan room interface circuit 132 that a patient positioning system 134 receives commands to move the patient to desired positions during the scan.

The digitized magnetic resonance signal samples produced by the RF system 120 are received by the data acquisition server 112. The data acquisition server 112 operates in response to instructions downloaded from the operator workstation 102 to receive the real-time magnetic resonance data and provide buffer storage, such that no data is lost by data overrun. In some scans, the data acquisition server 112 does little more than pass the acquired magnetic resonance data to the data processor server 114. However, in scans that require information derived from acquired magnetic resonance data to control the further performance of the scan, the data acquisition server 112 is programmed to produce such information and convey it to the pulse sequence server 110. For example, during prescans, magnetic resonance data is acquired and used to calibrate the pulse sequence performed by the pulse sequence server 110. As another example, navigator signals may be acquired and used to adjust the operating parameters of the RF system 120 or the gradient system 118, or to control the view order in which k-space is sampled. In still another example, the data acquisition server 112 may also be employed to process magnetic resonance signals used to detect the arrival of a contrast agent in a magnetic resonance angiography (MRA) scan. By way of example, the data acquisition server 112 acquires magnetic resonance data and processes it in real-time to produce information that is used to control the scan.

The data processing server 114 receives magnetic resonance data from the data acquisition server 112 and processes it in accordance with instructions downloaded from the operator workstation 102. Such processing may, for example, include one or more of the following: reconstructing two-dimensional or three-dimensional images by performing a Fourier transformation of raw k-space data; performing other image reconstruction algorithms, such as iterative or backprojection reconstruction algorithms; applying filters to raw k-space data or to reconstructed images; generating functional magnetic resonance images; calculating motion or flow images; and so on.

Images reconstructed by the data processing server 114 are conveyed back to the operator workstation 102 where they are stored. Real-time images are stored in a data base memory cache (not shown in FIG. 1), from which they may be output to operator display 112 or a display 136 that is located near the magnet assembly 124 for use by attending physicians. Batch mode images or selected real time images are stored in a host database on disc storage 138. When such images have been reconstructed and transferred to storage, the data processing server 114 notifies the data store server 116 on the operator workstation 102. The operator workstation 102 may be used by an operator to archive the images, produce films, or send the images via a network to other facilities.

The MRI system 100 may also include one or more networked workstations 142. By way of example, a networked workstation 142 may include a display 144; one or more input devices 146, such as a keyboard and mouse; and a processor 148. The networked workstation 142 may be located within the same facility as the operator workstation 102, or in a different facility, such as a different healthcare institution or clinic.

The networked workstation 142, whether within the same facility or in a different facility as the operator workstation 102, may gain remote access to the data processing server 114 or data store server 116 via the communication system 117. Accordingly, multiple networked workstations 142 may have access to the data processing server 114 and the data store server 116. In this manner, magnetic resonance data, reconstructed images, or other data may exchanged between the data processing server 114 or the data store server 116 and the networked workstations 142, such that the data or images may be remotely processed by a networked workstation 142. This data may be exchanged in any suitable format, such as in accordance with the transmission control protocol (TCP), the internet protocol (IP), or other known or suitable protocols.

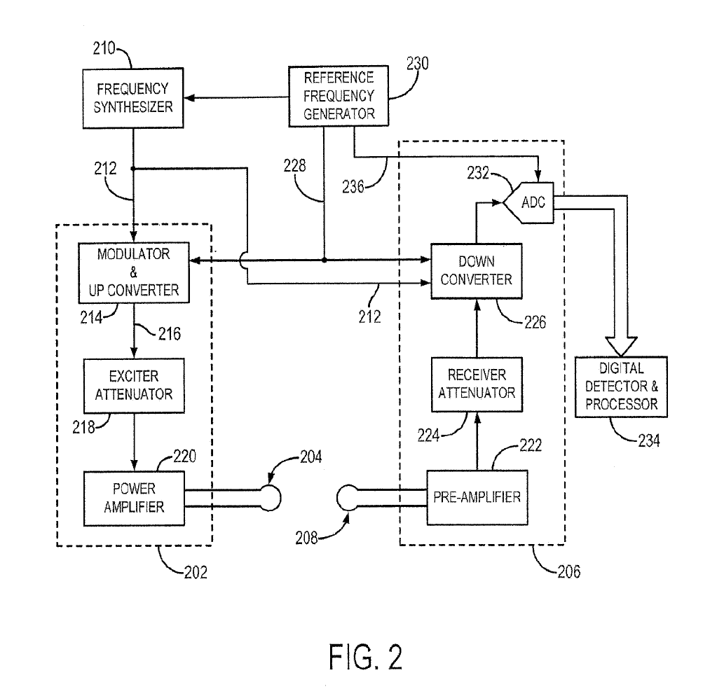

With reference to FIG. 2, the RF system 120 of FIG. 1 will be further described. The RF system 120 includes a transmission channel 202 that produces a prescribed RF excitation field. The base, or carrier, frequency of this RF excitation field is produced under control of a frequency synthesizer 210 that receives a set of digital signals from the pulse sequence server 110. These digital signals indicate the frequency and phase of the RF carrier signal produced at an output 212. The RF carrier is applied to a modulator and up converter 214 where its amplitude is modulated in response to a signal, R(t), also received from the pulse sequence server 110. The signal, R(t), defines the envelope of the RF excitation pulse to be produced and is produced by sequentially reading out a series of stored digital values. These stored digital values may be changed to enable any desired RF pulse envelope to be produced.

The magnitude of the RF excitation pulse produced at output 216 is attenuated by an exciter attenuator circuit 218 that receives a digital command from the pulse sequence server 110. The attenuated RF excitation pulses are then applied to a power amplifier 220 that drives the RF transmission coil 204.

The MR signal produced by the subject is picked up by the RF receiver coil 208 and applied through a preamplifier 222 to the input of a receiver attenuator 224. The receiver attenuator 224 further amplifies the signal by an amount determined by a digital attenuation signal received from the pulse sequence server 110. The received signal is at or around the Larmor frequency, and this high frequency signal is down converted in a two step process by a down converter 226. The down converter 226 first mixes the MR signal with the carrier signal on line 212 and then mixes the resulting difference signal with a reference signal on line 228 that is produced by a reference frequency generator 230. The down converted MR signal is applied to the input of an analog-to-digital (“A/D”) converter 232 that samples and digitizes the analog signal. The sampled and digitized signal is then applied to a digital detector and signal processor 234 that produces 16-bit in-phase (I) values and 16-bit quadrature (Q) values corresponding to the received signal. The resulting stream of digitized I and Q values of the received signal are output to the data acquisition server 112. In addition to generating the reference signal on line 228, the reference frequency generator 230 also generates a sampling signal on line 236 that is applied to the A/D converter 232.

The basic MR systems and principles described above may be used to inform the design of other MR systems that share similar components but operate at very-different parameters. In one example, a low-field magnetic resonance imaging (IfMRI) system utilizes much of the above-described hardware, but has substantially reduced hardware requirements and a smaller hardware footprint.

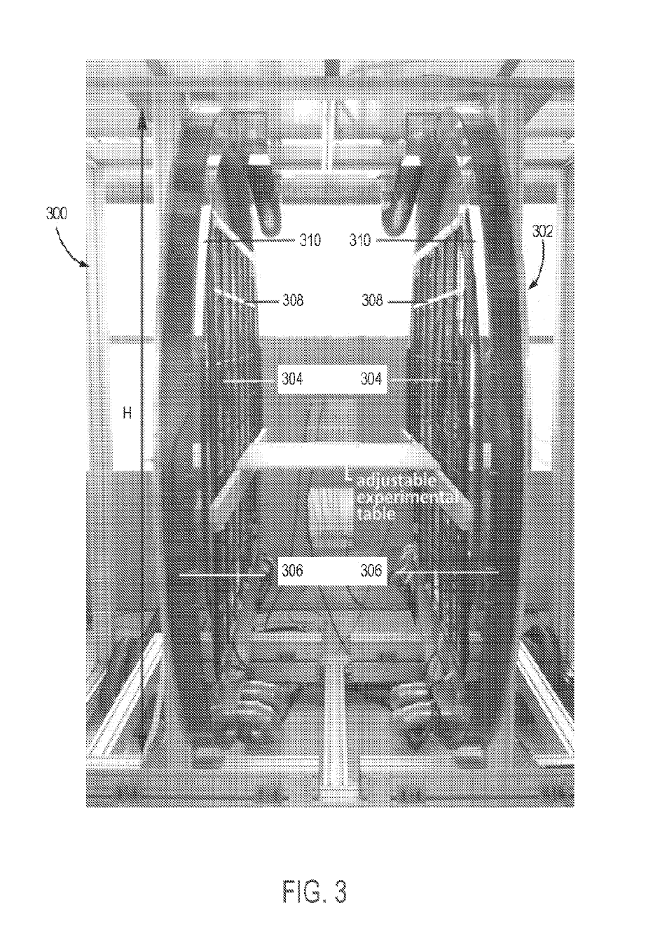

For example, referring to FIG. 3, a system 300 is illustrated that, instead of a 1.5 T or greater static magnetic field, utilizes a substantially smaller magnetic field. That is, in FIG. 3, as a non-limiting example, an electromagnet-based scanner is illustrated that may have a magnetic field of less than 10 mT and, in some cases, a magnetic field of 6.5 mT or less. The system 300 includes a biplanar 6.5 mT electromagnet (B0) 302 that, for example, may be formed by inner B0 coils 304 and outer B0 coils 306. Biplanar gradients 308 may extend across the B0 electromagnet 302.

The system 300 may be tailored for ¹H imaging by achieving a high B0 stability, high gradient slew rates, and low overall noise. To achieve these ends, a power supply, for example, with +/−1 ppm stability over 20 min and +/−2 ppm stability over 8 h, may be used and high current shielded cables may be deployed throughout the system 300. In one non-limiting example, a power supply was adapted from a System 854 T, produced by Danfysik, Taastrup, Denmark. The system 300 can operate inside a double-screened enclosure (ETS-Lindgren, St. Louis, Mo.) with a RF noise attenuation factor of 100 dB from 100 kHz to 1 GHz. In this example, the system may have a height, H, that is, as a non-limiting example, 220 cm. A cooling systems 310, such as may include air-cooling ducts, may be included.

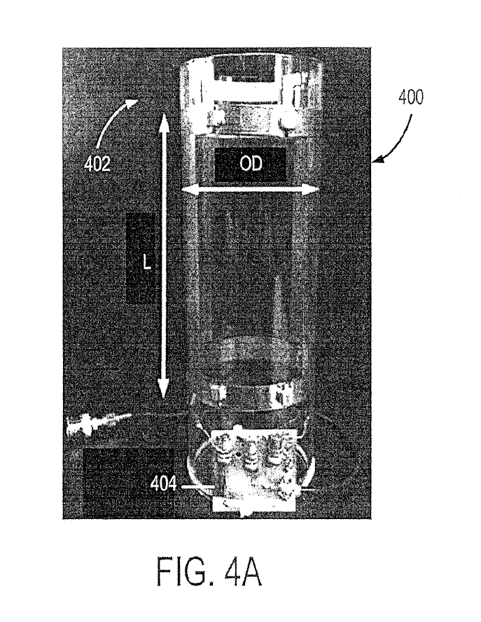

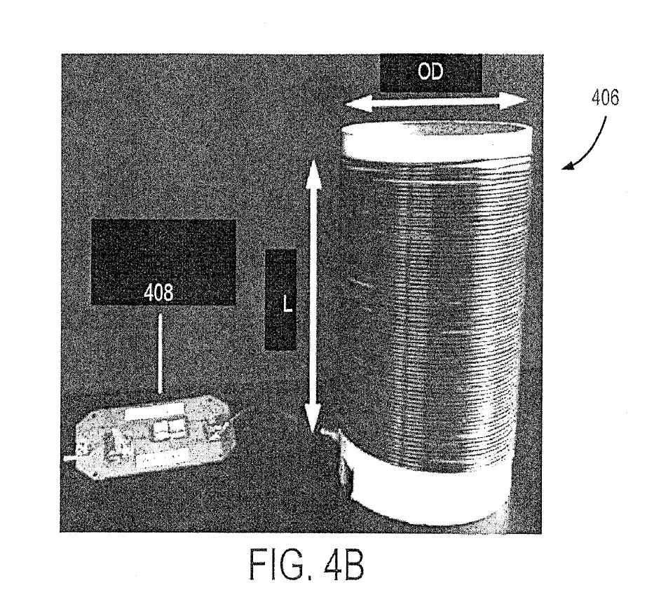

The transfer of electron spin polarization to dipolar or scalar coupled nuclear spins via the Overhauser effect uses high-power irradiation of the electron spin resonance. As shown in FIG. 4A, a Alderman-Grant, electron paramagnetic resonance (EPR) coil 400 is illustrated. As one non-limiting example, the EPR coil 400 may have an outer diameter (OD) of 7 cm, and a length (L) of 13 cm. The EPR coil 400 includes guard rings 402 that aid in controlling sample heating and saturating the electron spin resonance of, for example, the nitroxide radical 4-hydroxy TEMPO. TEMPOL (4-hydroxy-TEMPO) may be detected with very-high sensitivity by performing an OMRI process. TEMPOL, as used herein, refers to 4-Hydroxy-TEMPO 4-hydroxy-2,2,6,6-tetramethylpiperidin-1-oxyl. It is a heterocyclic compound. It may be used as an exogencusly administered free radical probe.

The electron spin resonance is split into three transitions by the hyperfine coupling of the spin 1 ¹⁴N nucleus (at 6.5 mT, there still exist other transitions described by the Breit-Rabi equations but their transition probabilities are small and ignored here). As SAR scales with ω², the EPR coil 400 can be tuned to the low energy transition of 140.8 MHz using a tuning/matching circuit 404 to control SAR.

The EPR coil 400 can be arranged inside a NMR coil 406 that is designed for NMR/MRI excitation, as illustrated in FIG. 4B. The NMR coil 406 may be formed as a solenoid, as a non-limiting example, and when used with the non-limiting example EPR coil 400 described above, the solenoid coil 406 may have an outer diameter (OD) of 10 cm and a length (L) of 16 cm. The NMR coil 406 may include a respective tuning/matching circuit 408. The coils 400, 406 may be oriented such that their respective B1 fields are perpendicular to each other and to the B0 field of the MR system. Placing the NMR coil 406 outside the ESR coil 400 sacrifices NMR filling factor to gain larger B1 for electron spin saturation because DNP signal enhancement (defined as <lz>=l₀, where l₀ is the thermal equilibrium NMR signal and <lz> is the DNP signal) is limited by the available RF power.

A challenge to performing low-field MRI is to address the relatively low signal-to-noise ratio (SNR) resulting from the low field strengths employed (e.g., 2 T and below). In particular, the SNR of an MR signal is related to the strength of the main magnetic field B0. Thus, at the low field strengths involved in low-field MRI, relatively weak MR signals are produced resulting in substantially lower SNR. A technique for addressing the low SNR is to repeat MR data acquisition at a given “location” multiple times (e.g., by repeating a pulse sequence with the same operating parameters) and averaging the obtained MR signals that result. However, while averaging improves SNR, the repeat acquisitions increase total acquisition times. To address this issue, the inventors have developed a number of “rapid averaging” pulse sequences that employ averaging to increase the signal to noise ratio of the acquired MR signal, but allow for such averaging to be performed rapidly thereby reducing the overall amount of time to acquire an image. Such rapid averaging pulse sequences result in improved MR imaging in low-SNR (e.g., low-field) environments. The term “average” is used herein to describe any type of scheme for combining the signals, including absolute average (e.g., mean), weighted average, or any other technique that can be used to increase the SNR by combining MR data from multiple acquisitions.

The inventors have developed rapid averaging pulse sequences that are specifically designed for use and/or optimal performance in the low-field context. Referred to herein as low-field refocusing (LFR) pulse sequences, these sequences have a portion of the pulse sequence configured to refocus the magnetization to a known state. For example, an LFR pulse sequence may comprise at least one RF pulse that induces a relatively large flip angle and a refocusing stage, after a period of relaxation during which acquisition occurs, that drives the net magnetization vector toward that same relatively large flip angle. Pulse sequences that drive the magnetization towards a steady state as opposed to allowing the magnetization to fully relax are referred to as steady-state pulse sequences, of which SSFP sequences are an example.

A refocusing stage may apply gradient fields having strengths and polarities such that the sum of the fields strengths of each gradient field across the duration of a pulse repetition period is substantially zero (or intended to be near zero). For example, gradient fields applied during the refocusing phase may be equal and opposite to the gradient fields applied during an encoding phase. Such sequences are referred to as “balanced,” of which b-SSFP is an example.

Importantly, LFR pulse sequences do not require waiting for the net magnetization to realign with the B0 field between successive MR data acquisitions (e.g., successive acquisitions may be obtained without needing to wait for the transverse magnetization vector to decrease to 0). In this way, successive acquisitions may be performed more rapidly. Additionally, since the magnetization does not need to be fully reestablished, the duration of the pulses can be reduced. The inventors have recognized that the steady state aspect of the magnetization of these sequences also allows the duration of EPR pulses to be significantly reduced. Specifically, because electron saturation does not need to be fully re-established (i.e., because it is not allowed to fully relax and is instead driven toward steady state), EPR pulses can be relatively short (e.g., on the order of 10 ms as opposed to 1 second in conventional sequences). As a result, SAR can be significantly reduced. Provided below is an example of using an exemplary b-SSFP in combination with in-sequence EPR pulses provided during the gradient phase encode, in accordance with some embodiments.

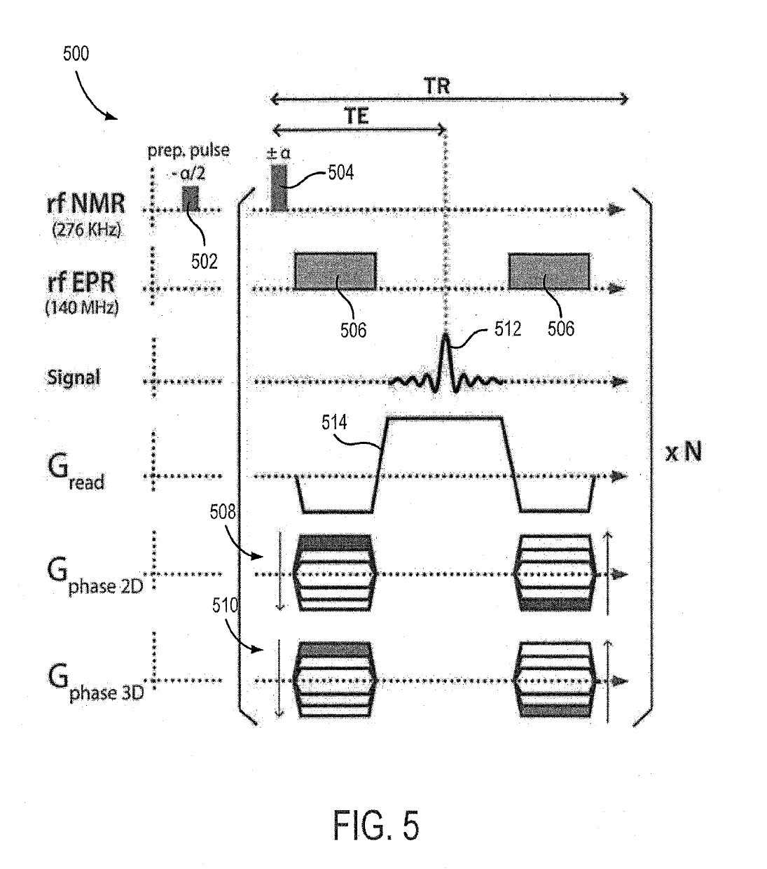

Referring to FIG. 5, for imaging, a variation on a 3D balanced stead-state free procession (b-SSFP) pulse sequence 500 may be used in accordance with the present disclosure. The b-SSFP includes an initial −α/2 preparation pulse 502 followed by a train of alternating +/−α excitation pulses 504. The +/−α excitation pulses 504 are separated by a repetition time (TR) and echo time (TE) interval between the +/−a excitation pulses 504 and the first a pulse 502 of, for example, 2 ms. One benefit of using a preparation pulse 502 is that it controls against large fluctuations of the pre-steady state signal that could produce image artifacts and thus could not be used for signal acquisition.

A selective RF excitation pulse 506 that is coordinated with a 2D phase encoding gradient pulse 508 and a 3D phase encoding gradient pulse 510 are applied to position encode the NMR signal 512 along one direction in the slice. A readout gradient pulse 514 is also applied to position encode the NMR signal 512 along a second, orthogonal direction in the slice. To maintain the steady state condition, the integrals of the gradients each sum to zero. It is important to note that, in the above-described pulse sequence 500, separate EPR saturation step is not required, unlike traditional OMRI sequences. The sequence is a b-SSFP sequence with the addition of EPR (Overhauser) irradiation 506 during the balanced phase encode gradients 508, 510, 514. Thus, no EPR saturation pulses are applied when not performing the MRI pulse sequence. Said another way, the EPR pulses are only performed during or interleaved with the MRI pulse sequence, such as the above-described b-SSFP pulse sequence.

In b-SSFP, a desired flip angle α is given by:

$$cos ( α ) - \frac{{T}_{1} / {T}_{2} - 1}{{T}_{1} / {T}_{2} + 1} .$$

In one experiment using the above-described systems and methods, a Redstone NMR console (Tecmag, Houston, Tex.) was used for data acquisition and controlled the gradients and RF channels. The console has two transmit channels allowing for both NMR and EPR irradiation. A 100 W, CW amplifier (BT00100-DeltaB-CW) was used for EPR saturation and a 500 W pulsed amplifier (BT00500-AlphaS) was used for NMR (from both Tomco Technologies, Stepney, Australia).

A configurable imaging phantom was built for these experiments. Various pieces designed to demonstrate resolution in three dimensions and test the ability to resolve sharp edges in under-sampled k-space were 3D printed in polycarbonate on a Fortus 360 mc (StrataSys, Eden Prairie, Minn.). The 3D printed pieces were stacked inside a 5.5 cm ID, 13 cm long machined polycarbonate cylinder. One advantage of this phantom is the flexibility to design and 3D print any desired structure for a particular experiment. The cylinder was then filled with 250 mL of 2.5 mM 4-hydroxy TEMPO solution in water, and a leak-tight polycarbonate cap inserted.

Imaging experiments were performed in two different phantom stacking configurations. The first stacked geometry consists of two interlocking sets of a trio of stepwise-smooth cones and was used to evaluate the 3D character of the sequence and the minimum structure sizes that can be resolved for round-shaped objects. The second configuration used more complex structures with finer details to assess the sequence performance, ability to resolve small in-plane structures, and the results of undersampling on sharp edges. Fiber optic temperature probes (Luxtron, LumaSense Technologies, Santa Clara, Calif.) were placed inside the phantom and near a ring capacitor on the EPR coil during tests of the imaging sequence to monitor sample and coil temperatures.

In the above-described phantom studies, T1 and T2 were measured to be 545 ms and 488 ms, respectively, which leads to an optimal flip angle of α˜90 degrees. Bloch simulations were performed for a sequence without phase gradients (i.e., at the center of k-space), both with and without EPR irradiation to model the buildup and time course of transverse magnetization as well as the signal enhancement provided by DNP. The simulations were run in MATLAB (MathWorks, Natick, Mass.) using code written in-house. Input parameters to the simulations were the measured T1 and T2 relaxation times, the measured enhancement provided by DNP with a 1.5 s EPR pulse (˜3×1H T1) in a 1D spectroscopy experiment (−44.5 fold enhancement), TR/TE−54/27 ms and α−90 degrees. This negative enhancement results from Overhauser DNP pumping into the opposite spin nuclear ground state compared with the Boltzmann case. This sign is notable for the simulations. In the OMRI experiments with these parameters, a total bandwidth MA/1/49091 Hz, and a 71 Hz bandwidth per pixel, were run and compared with the simulations.

The 3D imaging experiment was performed initially with full Cartesian acquisition of k-space. The sequence was set with TR/TE−54/27 ms, a 256×64×112 mm3 field of view, and acquisition matrix of 128×64×32, resulting in a 2×1×3.5 mm3 voxel size. The balanced phase gradient durations were both set to 20 ms to reach the desired in-plane spatial resolution when the gradient amplifiers were at maximum power. The readout duration was 14 ms with 9091 Hz bandwidth and total acquisition time was 114 s for fully sampled k-space. These experiments were highly successful by achieving a very stable magnetic field as off-resonance effects can distort the image and cause severe banding artifacts.

It should be noted that the application of EPR saturation pulses while the MR gradients are on is possible because the maximum gradient strength is low, for example, 0.1 gauss cm, giving a spread in electron resonance frequencies across the 5.5 cm sample (in-plane dimension) of ˜1.54 MHz. The loaded Q of the EPR coil was determined using a vector network analyzer and an untuned pick up coil to measure the transmission response of the EPR coil. The measured Q of 62 corresponds to a bandwidth of ˜2.3 MHz, thus the spread in electron spin frequencies during the phase encode step is well covered.

Most images are sparse in the sense that they can be accurately represented with fewer coefficients than one would assume given their spectral bandwidth. Compressed sensing (CS) is a framework for exploiting sparsity to reconstruct high-fidelity MR images from undersampled k-space datasets that do not fulfill the Nyquist sampling theorem. In CS image reconstruction, image sparsity is enforced by truncating the small coefficients of an object's representation in a sparse basis, typically chosen to be a wavelet transform domain. During image reconstruction, the data are transformed from k-space (the sensing basis) into the wavelet basis via a sparsifying transform, c, taken for this work to be the Dirichlet wavelet transform.

CS uses norms to modify the objective function that is optimized during image reconstruction. To understand the role of norms in the objective function, it is helpful to recall standard Fourier reconstruction. For a discrete image m, Fourier operator F, and k-space dataset y, the L2-norm, ∥Fm−y∥₂−(Σₗ|(Fm)ᵢ−yᵢ|²)^{1/2}, is implicitly used to find an image whose Fourier transform differs as little as possible from the k-space data in the Euclidean sense. For fully sampled data, the least squares solution is provided by the Fourier transform. In the case of underdetermined matrix problems (as when the k-space data is undersampled), the L2-norm may be additionally used to constrain image reconstruction so as to reduce the noise (an approach known as Tikhonov regularization). However, when the L2-norm is used in this way, it functions as a low-pass filter, penalizing noise at the expense of introducing bias. It does not promote image sparsity. By contrast, the L1-norm, defined as ∥x∥ₗ−Σᵢ|xᵢ| for an arbitrary function x, has a tendency to preserve edges and large coefficients, e.g., for neighboring voxels {0,3,0} the L2-norm will tend to penalize the difference toward {1,1,1}, while the L1-norm of both cases is the same, preserving the edge.

The ability of the L1-norm to preserve large coefficients makes it an appealing choice for enforcing sparsity in images. In the CS framework, the L1-norm is applied to the wavelet transform of the image, where it naturally selects the large coefficients representing image features while reducing the small coefficients corresponding to noise and incoherent artifacts. For additional denoising and artifact suppression, a finite difference norm (a discrete implementation of the Total Variation, or TV, norm) may be applied in the image domain. This norm has been shown to preserve object edges while eliminating noise. The resulting image reconstruction problem is expressed as a balance between the L1-norm constraints and the L2-norm data consistency constraint:

min[∥Fᵤm−y∥₂+α∥ψm∥₁+βTV(m)];

where Fᵤ is the undersampled Fourier transform operator, y is the undersampled k-space data, and coefficients α and β weight the relative contributions of each norm to the final image. A variety of algorithms are available for minimizing this nonlinear objective function. For this particular implementation CS for OMRI b-SSFP, a variety of considerations may be made.

The use of CS in MRI relies on the possibility to acquire a priori compressed information and be able to reconstruct the original image as if the latter was fully sampled. In the context of data acquisition, this motivates the use of undersampling. CS has been found to work best when k-space is randomly undersampled to produce incoherent artifacts rather than the familiar wrap-around ghosts due to field-of-view contraction when k-space lines are skipped in a regular coherent pattern as is done in conventional parallel imaging.

In accordance with one non-limiting example, a choice may be made to acquire random lines of k-space in the phase-encode directions (ky, kz) following a gaussian probability density function. The readout direction may be fully sampled. The standard deviations of the sampling pattern as a fraction of the field-of-view along y and z, σ_{y}, and σ_{z}, respectively, may be adjusted to preserve adequate high-frequency information for each undersampling rate.

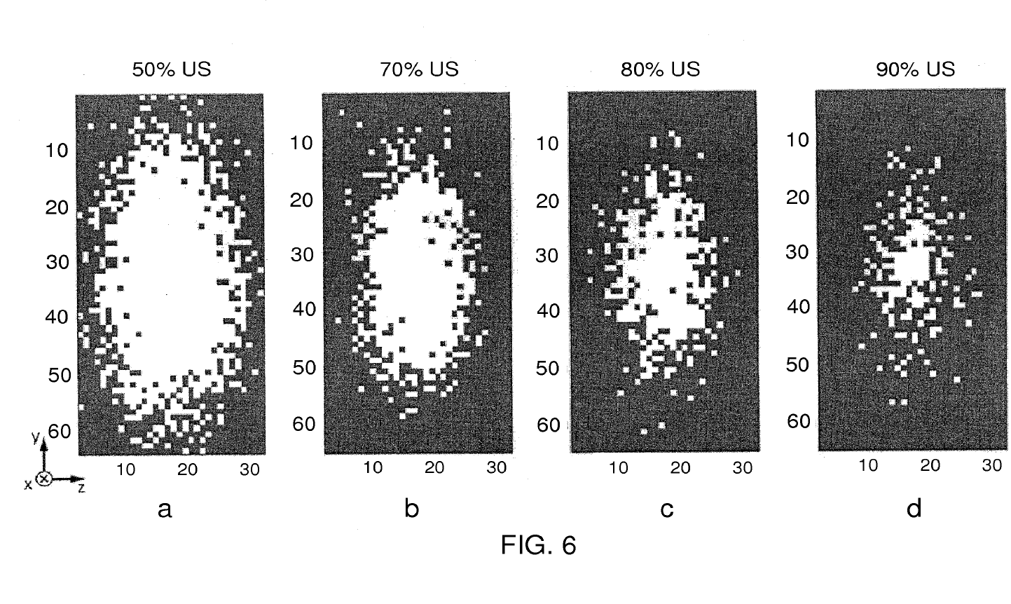

In one experiment, four undersampling fractions of 50, 70, 80, and 90 percent were investigated. The undersampling patterns are shown in FIG. 6A-6D.

On the acquisition side, this resulted in programming different phase encode tables for each undersampled sequence. The total acquisition time for each undersampling rate is shown in Table 1 below.

| | | Maximum | | |
|---|---|---|---|---|
| | Acq. | SNR | | |
| | time (s) | No CS | CS | MAE |
| Configuration 1 | | | | |
| Fully sampled | 114 | 23 | 40.6 | |
| 50% Undersampling | 56 | 35.8 | 75.8 | 0.073 ± 0.006 |
| 70% Undersampling | 33 | 44.6 | 95 | 0.072 ± 0.008 |
| 80% Undersampling | 21 | 64.3 | 160 | 0.112 ± 0.011 |
| 90% Undersampling | 10 | 69.8 | 148 | 0.149 ± 0.014 |
| Configuration 2 | | | | |
| Fully sampled | 114 | 24.6 | 42.6 | |
| 50% Undersampling | 56 | 30.47 | 49.7 | 0.049 ± 0.005 |
| 70% Undersampling | 33 | 42 | 78.3 | 0.059 ± 0.010 |
| 80% Undersampling | 21 | 49.9 | 94.7 | 0.100 ± 0.013 |
| 90% Undersampling | 10 | 58.1 | 88.3 | 0.114 ± 0.014 |

To perform image reconstruction according to the L1-norm and the data consistency constraints, the Sparse MRI code was used. This code solves the optimization problem using a nonlinear conjugate gradient method along with backtracking line-search as described in Lustig M, Donoho D, Pauly J M. Sparse MRI: the application of compressed sensing for rapid MR imaging. Magn Reson Med 2007; 58:1182-1195, which is incorporated herein by reference in its entirety. The parameters for the wavelet and image domain norms were tuned to produce low-noise images with preserved object features. The missing values in the acquired k-space data were made identically zero. To separate out the data into slices, a Fourier transform was performed along the readout direction (x). Each sagittal slice of kspace data (y-z plane) was then reconstructed by the Sparse MRI algorithm. After all slices were reconstructed, the resulting 3D block of image domain data was then displayed as transverse (x-y) slices. The computation time for a laptop equipped with a 2.3 GHz quad-core processor was 4.5 min, permitting CS image reconstruction immediately following k-space acquisition.

Steady-State Signal with Embedded EPR Pulses

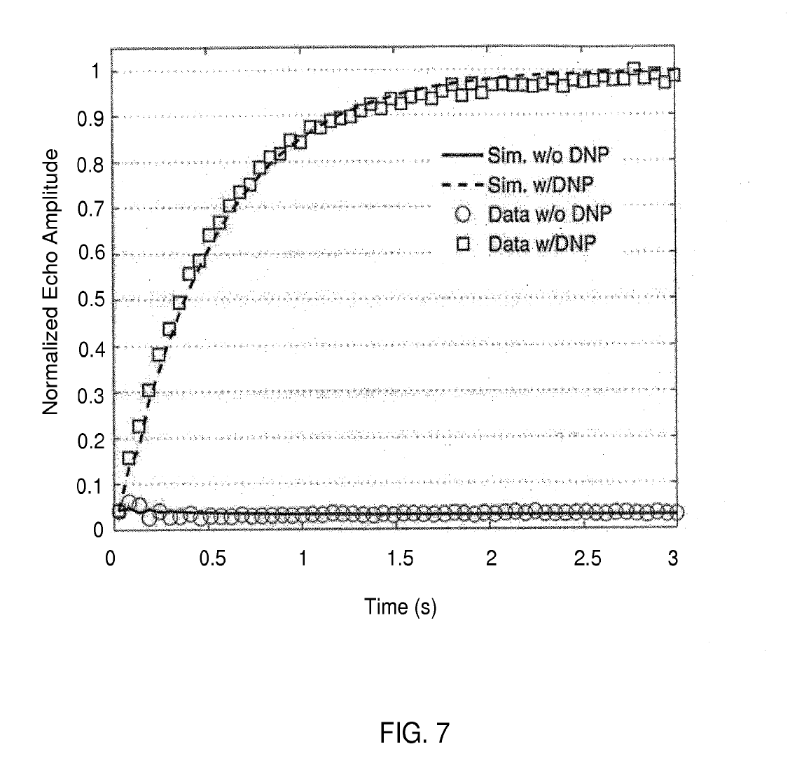

To understand the approach of transverse magnetization to steady state with embedded EPR pulses in the sequence, Bloch simulations were performed without the phase encode gradients and compared with acquired data. The results are shown in FIG. 7. The data was normalized such that the maximum measured signal and the maximum simulated signal were both set to 1. The experimental data with DNP (□) begins at thermal equilibrium, but rapidly builds up to 30 times that of the non-DNP data (◯). This build up corresponds to the T1 relaxation time of the sample (545 ms). The signal reaches ˜90 percent of its steady state value after 24 echoes, or 1.3 s, and the simulation is in good agreement with the data (dashed line; not a fit).

Images reconstructed from fully sampled k-space and from 50, 70, 80, and 90 percent undersampling were created. For both phantom configurations, 50 and 70 percent undersampling reproduces the fully sampled images well. Even small structures, such as 2 mm diameter holes, 1 and 1.5 mm solid separators, and 2.5 mm holes are well resolved at 70 percent undersampling. For 80 and 90 percent undersampling, most of the structures are still visible although substantial blurring and ghosting artifacts begin to appear. The maximum SNR was calculated from maximal signal amplitudes divided by two times the standard deviation of a user defined noise region before and after CS reconstruction and is shown in Table 1. The increase in SNR with undersampling rate is due to the undersampling pattern acting as an apodization filter that removes high spatial frequencies from k-space. However, all images show an increase in SNR after CS reconstruction. The SNR enhancement using CS increases with the initial SNR of the image and ranges from about 1.5 to 2.5.

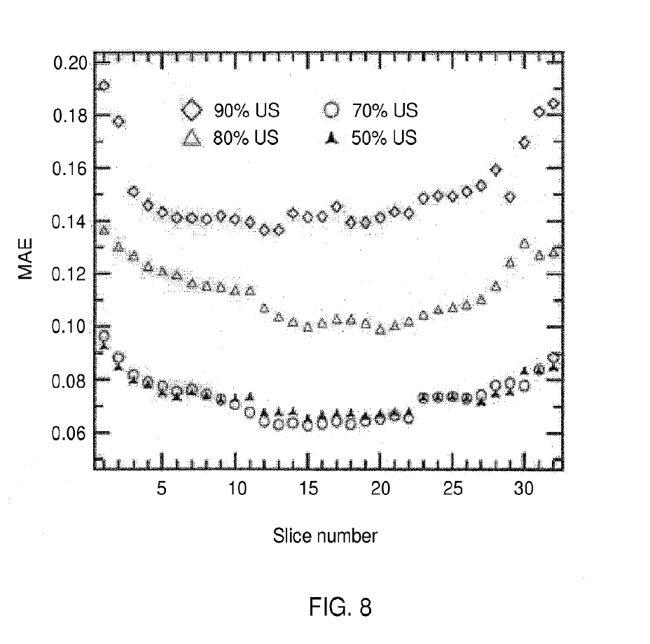

To quantify the errors that occur in the undersampled images, the mean absolute error (MAE) was calculated for each image, as shown in Table 1. The MAE was calculated by first thresholding the images such that only points that were five times greater than the noise (σₙ) were kept. The undersampled image was then subtracted from the fully sampled image and all non-zero values counted as an error. As seen in Table 1, the MAEs for the 50 and 70 percent undersampling rates are small and comparable while those for 80 and 90 percent increase significantly. The MAE for each of the 32 phase encodes gradients along z for configurations is shown in FIG. 8 for all undersampling rates. In particular, FIG. 8 shows the configuration in 50 percent US (solid triangles), 70 percent US (circles), 80 percent US (hollow trianges), and 90 percent US (diamond). There is little difference across the entire sample between 50 and 70 percent, again showing that the image is well reproduced with only 30 percent of the k-space data. Losses in SNR due to the B1 profile of the EPR coil on slices 1-5 and 25-32 result in increased MAE values for all undersampling rates.

One challenge that could limit the use of OMRI is that the high power RF pulses necessary for DNP lead to high SAR. Two methods were used to estimate SAR. A fiber optic temperature probe was placed inside the sample and the fully sampled k-space sequence was run several times, waiting several minutes in between runs to allow the EPR coil to cool. The maximum measured temperature increase was 0.4 degrees C. No temperature increase was measured for any of the undersampled sequences. Estimating SAR˜cT=Δt, where c is the specific heat, ΔT is the temperature change and Δt is the time of the sequence gives SAR−15 W kg1. This may represent a lower limit as heat may have dissipated during the sequence. As a second method, the power dissipated in the sample was estimated using:

Pₛₐₘₚₗₑ−P_{coil}(1−Q_{loaded}/Q_{unloaded})

The forward power was measured using a directional coupler (Model 3020A, Narda Microwave, Hauppauge, N.Y.) and power meter (V3500A, Agilent Technologies, Santa Clara, Calif.), and the maximum forward power to the coil was ˜62 W. The loaded Q was measured to be 52 while the unloaded Q was 62. Thus, the power to the sample during an EPR pulse is −10 W. The EPR irradiation is on for 73 percent of TR and the sample mass is 0.25 kg, therefore SAR−29 W kg1.

The 50 percent undersampled images have high SNR and accurately represent the phantom. Therefore, the forward power was reduced to the coil by factors of 2, 4, 8, and 16 to investigate how much the SAR could be reduced (thusly reducing the Overhauser enhancement) while maintaining high image quality.

The results are shown in Table 2.

Max. SNR

| Power to EPR coil (W) | No CS | CS |
|---|---|---|
| 62 | 36 | 75 |
| 31 | 29.3 | 48 |
| 15.5 | 21 | 26.4 |
| 7.8 | 15.2 | 18.2 |
| 3.9 | 11.4 | 16.2 |

Image quality is well maintained for 31 and 15.5 W forward power corresponding to an estimated SAR of ˜14.5 and 7.25 W kg1, respectively.

The 3D Overhauser-enhanced b-SSFP sequence presented here in combination with CS and undersampling techniques was used to attain a 1×2×3.5 mm3 voxel size in phantom studies in 33 s (70 percent undersampling) at 6.5 mT. The resulting CS reconstructed image was nearly identical to the original, fully-sampled image and had ˜2 times higher SNR. This was achieved by inserting the EPR saturation pulses within TR during the prephase/rephase gradients, thus, removing the time consuming prepolarization step as in other OMRI sequences. As shown in the experiments and simulations, a large steady-state signal is quickly reached with 90 percent of the maximum signal reached in <1.5 s, and constant polarization in the sample is maintained during the remainder of the acquisition. This controls the need to correct acquisitions for T1 decay and to rectify undesirable phase shifts that can occur when using prepolarization techniques. The maximum signal with b-SSFP at thermal equilibrium is given by:

$${M}_{ss} = \frac{1}{2} {M}_{0} \sqrt{{T}_{2} / {T}_{1}} = 0.47 {M}_{0} .$$

Overhauser saturation pulses during the phase gradient increases MSS by ˜30 for the sample used here, thus allowing high SNR images comparable to those obtained with conventional OMRI techniques. The simulations provide a reliable tool to optimize the phase encode gradient durations depending on T1 and T2.

The application of EPR saturation pulses during the balanced phase encode gradient events is our first major source of acceleration. This allows us to acquire images twice as fast as spin echo OMRI sequences that have been used with nearly seven times higher spatial resolution (1×2×3.5 mm3 vs. 1.25×1.25×30 mm³). This is possible by covering the spread in electron spin frequencies in the phantom when the maximum 0.1 gauss cm⁻¹ phase encode gradient was turned on. This sets an upper bound on the Q factor of the EPR coil, or alternatively, the maximum gradient strength that can be used for these experiments. While the maximum steady-state DNP enhancements would benefit from a higher Q coil, the goal of maintaining nearly constant signal enhancement across the sample during imaging would suffer. However, when the EPR irradiation occurs as separate step before imaging as in other OMRI sequences, the DNP signal is also not constant across the image due to the decay of polarization, so a compromise of higher gradient strength for uneven DNP polarization may be acceptable.

Partial sampling of k-space (and subsequent reconstruction via CS) can be used to provide another substantial acceleration factor. In the case of 70 percent undersampling, this can be used to achieve an additional 3.5 fold acceleration, while keeping the voxel size unchanged, thus resulting in seven times faster acquisition compared with recently published work, Sun Z, Li H, Petryakov S, Samouilov A, Zweier J L. In vivo proton electron double resonance imaging of mice with fast spin echo pulse sequence. J Magn Reson Imaging 2012; 35:471-475. By undersampling in each phase encode direction according to a gaussian probability density function, the center of k-space is emphasized, preserving image contrast without substantially sacrificing the high frequency information at the edge of k-space. For the σ_{y}, z's in the experiments described above, the 50 percent and 70 percent undersampling rates accurately reproduced the image for different random samplings of k-space. In these experiments, Cartesian sampling was used; however, alternative sampling trajectories, such as spiral and radial, can likewise be used and offer more flexibility in the design of 3D incoherent sampling sequences that are particularly well for the use of CS techniques.

CS performs natural denoising and brings an improvement in SNR. Incoherent artifacts resulting from subsampled k-space are efficiently suppressed using L1-norm constraints in the image and wavelet domains as previously detailed in the literature, such as Lustig M, Donoho D, Pauly J M. Sparse MRI: the application of compressed sensing for rapid MR imaging. Magn Reson Med 2007; 58:1182-1195. However, in the above-described experiments, more than 70 percent undersampling could not provide satisfying reconstruction in spite of high SNR. The incorporation of prior knowledge, such as in prior image constrained compressed sensing (PICCS) or highly constrained backprojection reconstructions imaging (HYPR) in the image reconstruction process can be used to overcome this constraint by partially recovering an irretrievable loss of information caused by heavy undersampling and further increase our temporal resolution. In addition, it is worth noting that the 4.5 min computation time for the CS reconstruction does not significantly penalize the time saved from undersampling.

The gain in temporal resolution obtained in the above-described example for 70 percent undersampling, around 1 s per acquired slice, provides insight for investigating cases where high temporal resolution is needed, such as monitoring the concentration change, oxidation, and metabolism of free radicals that correlate directly with organ functions and tissue health. In addition, shorter durations for the read and phase encode gradients could have been implemented to give significantly shorter acquisition times, but at the cost of a decreased spatial resolution. Likewise, doubling the gradient strength in read and both phase encode directions would allow one to reach 23 times higher spatial resolution for a fixed acquisition time.

Considering the SAR resulting from the sequence, the amount of power sent to the EPR coil can be decreased, for example by a factor of 4, while still keeping the SNR high, such as greater than 25 for a factor of 4 decrease. Even if a compromise has to be found between the desired spatial resolution of the image and sample heating due to the high power RF, the total amount of RF power sent to the sample during imaging is considerably reduced by the use of undersampling strategies. No temperature rise was measured in the sample for the 50 to 90 percent undersampling fractions with the maximum EPR power used in the above-described study. With the maximum available EPR power, images were acquired with an in-plane resolution of 1×1 mm² with 70 percent undersampling (while maintaining the 3.5 mm slice thickness). Total acquisition time was 65 s. This image displayed excellent in-plane resolution with very little blurring of the 1 mm features and high SNR. The images were acquired with a sufficiently long TR to obtain the desired in-plane resolution while keeping the gradient strength low enough for efficient EPR saturation during phase encoding. We note that the phantom used here has significantly longer T2 and T1 relaxation times than would be expected for in vivo applications. Bloch simulations were run to estimate how the current sequence would perform with relaxation times 10 times shorter than the phantom used here. Keeping all simulation parameters, but decreasing T1 to 55 ms and T2 to 49 ms resulted in less than a 15 percent reduction in signal intensity (compared with the dashed line in FIG. 7). While relaxation times comparable to TR tend to reduce signal, this is partially offset by a faster approach to steady state.

More likely to hamper the effectiveness of OMRI in vivo, however, is a decrease in the maximum DNP signal enhancement due to extra ¹H nuclear spin relaxation pathways that compete with relaxation caused by dipolar coupling to the electron spin. To observe this effect, simulations were run with the short T1 and T2 times above while decreasing the maximum DNP signal enhancement to 10 and 5. This reduced the steady state signal intensity by 80 and 90 percent, respectively, compared with the dashed line in FIG. 7. Although the signal is much smaller, it is still a factor of 7 and 3.5 times larger than the thermal equilibrium signal with the same parameters, and therefore still provides very useful contrast. In the case of injected free radical detection, this decrease in signal can be partially overcome by increasing the free radical concentration. For example, injection of 0.6 mL of 100 mM nitroxide radical in mice has been reported in recent work. Assuming 60-80 mL of blood per kg of bodyweight, the dilution factor is between 3 and 4 for a 30 g mouse, resulting in a nominal 29 mM free radical concentration, more than 10 times higher than the 2.5 mM used in the work presented here.

Thus, a new strategy for fast high-resolution 3D Overhauser MRI has been demonstrated using b-SSFP in a phantom containing 2.5 mM 4-hydroxy TEMPO solution at 6.5 mT. The embedding of EPR excitation pulses directly into the b-SSFP sequence can be used to eliminate need for a pre-polarization step used in other OMRI sequences, reducing the acquisition time and obviating the need for long, high power RF EPR pulses. The use of undersampling strategies and CS reconstruction algorithms further reduces imaging time. As described above, an undersampling rate of 70 percent gives unperceivable reconstruction errors when compared with the fully sampled data sets, allowing the acquisition of 32 slices in a volume within 33 s. As such, some of the primary limitations of Overhauser enhanced MRI as previously described in the literature, have been overcome. As such, the present disclosure provides drastically improved speed and resolution, and enables new opportunities for the measurement of free radicals in living organisms, and the study of dynamic processes, such as metabolism and flow.

Thus, electron spin resonance (ESR) irradiation for Overhauser-enhanced MRI is applied within the TR of a conventional MRI pulse sequence, typically during the phase-encode part of the sequence. Compared to conventional MRI sequences, no extra time is required to include ESR irradiation. As a result, this high speed OMRI sequence is about 10 times faster than the fastest OMRI sequences reported in the literature. As short ESR irradiation pulses occur every TR, nuclei polarization from the Overhauser effect is built up and reach a steady state after a time related to the relaxation properties of the sample (T1,T2) as well as the length of TR. Once a steady state is reached, signal enhancement from the Overhauser effect is constant. With the present disclosure, there is no need for long, high power pulses for ESR excitation.

High speed Overhauser-enhanced MRI can be used in soft condensed matter physics to image free radical species as contrast agents for the characterization of flow in porous and granular media. High speed Overhauser-enhanced MRI can be applied to the detection of free radical species in vivo. At low magnetic fields under 10 mT, high speed Overhauser-enhanced MRI can be used to probe free radical species in living organisms without overheating issues.

The present invention has been described in terms of one or more embodiments, and it should be appreciated that many equivalents, alternatives, variations, and modifications, aside from those expressly stated, are possible and within the scope of the invention.

1. A magnetic resonance imaging (MRI) system, comprising:
a magnet system configured to generate a static magnetic field about at least a region of interest (ROI) of a subject arranged in the MRI system;
at least one gradient coil configured to establish at least one magnetic gradient field with respect to the static magnetic field;
a radio frequency (RF) system configured to deliver excitation pulses to the subject;
a computer system programmed to:
control the at least one gradient coil and the RF system to perform a magnetic resonance (MR) imaging pulse sequence including application of phase encoding gradients;
while performing the MR pulse sequence, perform electron paramagnetic resonance (EPR) pulses at least during the application of the phase encoding gradients;
acquire data corresponding to signals from the subject excited by the MR pulse sequence and the EPR pulses; and
reconstruct, from the data, at least one image of the subject.

2. The system of claim 1 wherein the MRI system is a low-field MRI (IfMRI) system.

3. The system of claim 1 wherein the static magnetic field is less than 10 mT.

4. The system of claim 1 wherein the computer system is further programmed to perform a compressed sensing (CS) reconstruction process to reconstruct the at least one image of the subject.

5. The system of claim 4 wherein the computer is further programmed to use an L1-norm to select large coefficients in the data that represent image features while reducing small coefficients in the data that correspond to noise and incoherent artifacts.

6. The system of claim 4 wherein the computer is further programmed to use a finite difference norm to reduce noise in the at least one image of the subject.

7. The system of claim 4 wherein the computer system is further programmed to perform the CS reconstruction process as a balance between L1-norm constraints and L2-norm data consistency constraints.

8. The system of claim 1 wherein the computer is further programmed to control the at least one gradient coil and the RF system to perform the MR imaging pulse sequence as a balanced steady-state free precession (b-SSFP) pulse sequence.

9. The system of claim 8 wherein the computer is further programmed to EPR pulses are performed during balanced phase encode gradients of the b-SSFP pulse sequence.

10. The system of claim 1 wherein the computer is further programmed to perform the EPR pulses only within each repetition time (TR) of the MR pulse sequence.

11. A method for performing a medical imaging process, the method comprising:
arranging a subject to be imaged in a magnetic resonance imaging (MRI) system;
performing, using the MRI system, a magnetic resonance (MR) imaging pulse sequence having a repetition time (TR);
performing electron paramagnetic resonance (EPR) pulses while performing the MR pulse sequence, such that the EPR pulses are only performed within each TR of the MR pulse sequence;
acquiring data corresponding to signals from the subject excited by the MR pulse sequence and the ERR pulses; and
reconstructing, from the data, an image of the subject.

12. The method of claim 11 wherein no EPR saturation pulses are applied while not performing the MR pulse sequence

13. The method of claim 11 wherein the MR pulse sequence is a balanced steady state free precession (b-SSFP) pulse sequence.

14. The method of claim 13 wherein the EPR pulses include saturation pulses applied during at least one of pre-phase and rephrase gradients of the b-SSFP pulse sequence.

15. The method of claim 11 wherein the EPR pulses are performed during balanced phase encode gradients of the b-SSFP pulse sequence.

16. The method of claim 11 wherein the MRI system is a low-field MRI (IfMRI) system with a static magnetic field Is less than 10 mT.

17. The method of claim 11 wherein reconstructing includes performing a compressed sensing (CS) reconstruction process to reconstruct the at least one image of the subject.

18. The method of claim 17 wherein reconstructing further includes using use an L1-norm to select large coefficients in the data that represent image features while reducing small coefficients in the data that correspond to noise and incoherent artifacts.

19. The method of claim 17 further comprising using a finite difference norm to reduce noise in the at least one image of the subject.

20. The method of claim 17 wherein the CS reconstruction process balances between Li-norm constraints and L2-norm data consistency constraints.

21. A low-field magnetic resonance imaging system for detecting free radicals in a subject, the system comprising:
a plurality of magnetic components comprising:
at least one magnet configured to produce a low-field B0 magnetic field;
at least one gradient coil configured to produce magnetic fields to encode nuclear magnetic resonance signals emitted from the subject;
at least one radio-frequency coil configured to produce excitation pulses; and
at least one controller configured to control at least some of the plurality of magnetic components to produce pulse sequences wherein electron paramagnetic resonance pulses are applied during intervals in which the at least one gradient coil is operated.

22. The low-field magnetic resonance imaging system of claim 21, wherein the at least one controller controls the at least some of the plurality of magnetic components to produce steady-state free precession pulse sequences, and wherein the electron paramagnetic resonance pulses have a duration less than a corresponding nuclear T1.

23. The low-field magnetic resonance imaging system of claim 22, wherein the electron paramagnetic resonance pulses have a duration of approximately 10 milliseconds or less.

24. The low-field magnetic resonance imaging system of claim 22, wherein the steady-state free precession pulse sequences are balanced steady-state free precession pulse sequence.

25. The low-field magnetic resonance imaging system of claim 21, wherein the at least one magnet is configured to produce a B0 field of 0.2 T or less.

26. The low-field magnetic resonance imaging system of claim 21, wherein the at least one magnet is configured to produce a B0 field of 0.1 T or less.

27. The low-field magnetic resonance imaging system of claim 21, wherein the at least one magnet is configured to produce a B0 field of 10 mT or less.

28. The low-field magnetic resonance imaging system of claim 21, wherein the electron paramagnetic pulses are applied during a gradient encode phase of the pulse sequences.

29. The low-field magnetic resonance imaging system of claim 21, further comprising at least one radio-frequency coil configured to detect nuclear magnetic resonance signals emitted from the subject in response to the pulse sequences.

30. The low-field magnetic resonance imaging system of claim 29, wherein the at least one controller is configured to control the at least some of the magnetic components to produce pulse sequences and detect nuclear magnetic resonance signals using undersampling.

31. A low-field magnetic resonance imaging system for detecting free radicals in a subject, the system comprising:
a plurality of magnetic components comprising:
at least one magnet configured to produce a low-field B0 magnetic field;
at least one gradient coil configured to produce magnetic fields to encode magnetic resonance signals emitted from the subject;
at least one radio-frequency coil configured to produce excitation pulses; and
at least one controller to control at least some of the plurality of magnetic components to produce steady-state free precession pulse sequences having in-sequence electron paramagnetic resonance pulses, and wherein the electron paramagnetic resonance pulses have a duration less than a corresponding nuclear T1.

32. The low-field magnetic resonance imaging system of claim 31, wherein the electron paramagnetic resonance pulses have a duration of approximately 10 milliseconds or less.

33. The low-field magnetic resonance imaging system of claim 31, wherein the steady-state free precession pulse sequences are balanced steady-state free precession pulse sequences.

34. The low-field magnetic resonance imaging system of claim 31, wherein the at least one magnet is configured to produce a B0 field of 0.2 T or less.

35. The low-field magnetic resonance imaging system of claim 31, wherein the at least one magnet is configured to produce a B0 field of 0.1 T or less.

36. The low-field magnetic resonance imaging system of claim 31, wherein the at least one magnet is configured to produce a B0 field of 10 mT or less.

37. The low-field magnetic resonance imaging system of claim 31, wherein the electron paramagnetic pulses are applied during a gradient encode phase of the pulse sequences.

38. The low-field magnetic resonance imaging system of claim 31, further comprising at least one radio-frequency coil configured to detect nuclear magnetic resonance signals emitted from the subject in response to the pulse sequences.

39. The low-field magnetic resonance imaging system of claim 38, wherein the at least one controller is configured to control the at least some of the magnetic components to produce pulse sequences and detect nuclear magnetic resonance signals using undersampling.
